(19) United States
(12) Patent Application Publication
(10) Pub. No.: US 2009/0134439 A1
(43) Pub. Date: May 28, 2009

(54) CMOS IMAGE SENSOR AND METHOD FOR MANUFACTURING THE SAME

(76) Inventor: Sang-Chul Kim, Eumseong-gun (KR)

Correspondence Address: SHERR & VAUGHN, PLLC, 620 HERNDON PARKWAY, SUITE 200, HERNDON, VA, 20170, US

(21) Appl. No.: 12/323,014

(22) Filed: Nov. 25, 2008

(30) Foreign Application Priority Data
Nov. 26, 2007 (KR) 10-2007-0120890

(51) Int. Cl. H01L 31/0232; H01L 21/00

(52) U.S. Cl. 257/294; 438/70; 257/E31.127

(57) ABSTRACT

A CMOS Image Sensor (CIS) that minimizes light loss and achieves maximized performance. The CIS includes a plurality of metal wirings provided on and/or over a semiconductor substrate and surrounded, respectively, by a dielectric layer, a silicon layer deposited on and/or over the plurality of metal wirings, a photodiode and a plurality of transistors provided at the silicon layer, a color filter formed on and/or over the transistors, and via-contacts penetrated through the silicon layer, the photodiode being connected to the plurality of metal wirings by the via-contacts and gap-fillers. The photodiodes and the transistors are formed after forming the metal line.

The present application claims priority under 35 U.S.C. §119 to Korean Patent Application No. 10-2007-0120890 (filed on Nov. 26, 2007), which is hereby incorporated by reference in its entirety.

### BACKGROUND

Generally, an image sensor serves as a semiconductor device to electrically convert an optical image, and a charge coupled device (CCD) is a device in which individual metal-oxide-silicon (MOS) capacitors are arranged proximal to one another and are used to store and transfer charge carriers. A CMOS image sensor is a device widely used in cameras for mobile phones and personal computers, and other electronic instruments. As compared to CCD, the CMOS image sensor has a simplified drive method and can be integrated in a single chip together with a signal processing circuit, thereby realizing a system-on-Chip (SoC) and consequently, enabling a reduction in module size. A CIS is designed to employ a switching method for forming as many MOS transistors as pixels using a CMOS technology that uses control and signal processing circuits as peripheral circuits, and sequentially detecting outputs using the MOS transistors.

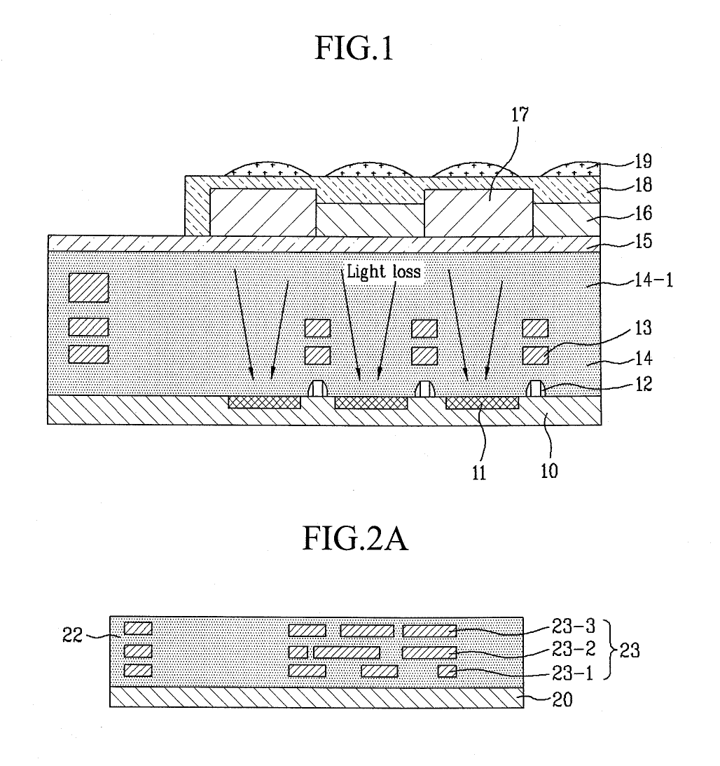

As illustrated in example FIG. 1, a CIS may include a light receiving part including photodiodes is located in a lower region of the CIS, and a color filter array (CFA) and microlenses are arranged in an uppermost region of the CIS overlapping and corresponding to the photodiodes. An inter dielectric layer, in which metal wirings M1 to M6 are formed, is interposed between the photodiodes and the CFA. Specifically, associated elements such as for example, transistors 12 for driving photodiodes 11 and control and signal processing circuits are formed on and/or over semiconductor substrate 10. A field oxide layer for device isolation may be formed prior to forming photodiodes 11. One or more dielectric layer 14 is formed on and/or over semiconductor substrate 10 and in turn, metal wirings 13 are formed on and/or over a respective one dielectric layer 14. Metal wirings 13 may have a multilayer form and in the drawing, an uppermost metal wiring is shown. Inter metal dielectric layer 14-1 is formed on and/or over the entire surface of semiconductor substrate 10 including metal wirings 13. Thereafter, passivation layer 15 is formed and planarized on and/or over inter metal dielectric layer 14-1. Passivation layer 15 may be composed of plasma enhanced nitride. A CFA process is performed for forming color filters 16 and 17, serving to realize color images, on and/or over passivation layer 15. Color filters 16 and 17 are covered with over coating layer (OCL) 18 having superior planarization characteristics, to assure a following uniform formation of microlenses 19. Microlenses 19 are formed on and/or over OCL 18 to correspond to the respective color filters 16 and 17. Microlenses 19 may be composed of a photosensitive layer.

The manufacturing process of the CMOS image sensor having the above-described configuration, more particularly, a metal wiring process such as a back-end-of-line (BEOL) wiring process is similar to a process for manufacturing a semiconductor device. In this case, different dielectric materials need to be used in order to form a pre-metal dielectric (PMD), inter-metal dielectric (IMD), passivation layer, and the like. For this reason, scattered reflection of light occurs at interfaces between the respective materials, causing deterioration in light sensitivity. With the configuration of such a CMOS image sensor, light loss occurs during passage through a BEOL layer. Furthermore, since photodiodes are provided only in a region having no metal layer, they have a difficulty in integration and require the use of light focusing lenses.

### SUMMARY

Embodiments relate to a CMOS image sensor and a method for manufacturing the same that arranges photodiodes and transistors on and/or over a BEOL layer to thereby minimize light loss and increase a photodiode area, which, in turn, optimizes integration of light.

Embodiments relate to a CMOS image sensor that may include at least one of the following: a plurality of metal wirings formed on and/or over a semiconductor substrate and surrounded, respectively, by a dielectric layer; a silicon layer formed on and/or over the plurality of metal wirings; a photodiode and a plurality of transistors formed on and/or over the silicon layer; a color filter formed on and/or over the transistors; and via-contacts penetrated through the silicon layer such that the photodiode is electrically connected to the metal wirings through the via-contacts and gap-fillers. In accordance with embodiments, the CMOS image sensor may further include: an anti-diffusion layer composed of a metal material formed on and/or over a surface of the metal wirings. The metal material may be any one of Ti, TiN, Ta, TaN and TiSiN.

In accordance with embodiments, the metal wirings may have a multilayer form and may be composed of any one of tungsten, aluminum, and copper.

Embodiments relate to a method for manufacturing a CMOS image sensor that may include at least one of the following steps: forming a plurality of layers of metal wirings on and/or over a semiconductor substrate so as to be surrounded by a dielectric layer; and then forming a silicon layer on and/or over the dielectric layer to cover the plurality of metal wirings; and then forming gap-fillers to connect the silicon layer and metal wirings to each other; and then forming a photodiode in the silicon layer by implanting a dopant into the silicon layer; and then forming a plurality of transistors on and/or over the silicon layer spaced apart a distance from the photodiode; and then forming a color filter on and/or over the transistors, whereby the photodiode is connected to the plurality of metal wirings by the gap-fillers and via-contacts penetrated through the silicon layer. In accordance with embodiments, forming the gap-fillers may include at least one of the following steps: coating the entire surface of the dielectric layer with a photosensitive layer and patterning the photosensitive layer via exposure and developing processes to form a mask; and then etching the inter metal dielectric layer from an uppermost layer of the metal wirings to the silicon layer using the mask as an etching barrier, so as to form via-holes exposing the metal wirings; and then forming an uppermost metal layer to be buried in the via-holes and planarizing the deposited metal layer using a chemical mechanical polishing (CMP) process, so as to form via-contacts.

Embodiments relate to a method that may include at least one of the following steps: forming a lower dielectric layer over a semiconductor substrate; and then forming a metal wiring over the lower dielectric layer; and then forming a silicon layer over the lower dielectric layer including the metal wiring; and then form a via-hole extending the silicon layer and the lower dielectric layer thereby exposing a portion of the metal wiring; and then forming a via contact in the via hole and contacting the metal wiring; and then forming a photodiode in the silicon layer and covering at least an upper portion of the via contacts by implanting dopant ions into the upper surface of the silicon layer; and then forming a transistor over the silicon layer and spaced laterally from the photodiodes; and then forming an upper dielectric over the silicon layer including the transistor and the photodiode; and then forming a color filter at the upper dielectric layer spatially corresponding to the photodiode. In accordance with embodiments, the photodiode and the transistor are formed after forming the metal line

### DRAWINGS

Example FIG. 1 illustrates a CMOS image sensor.

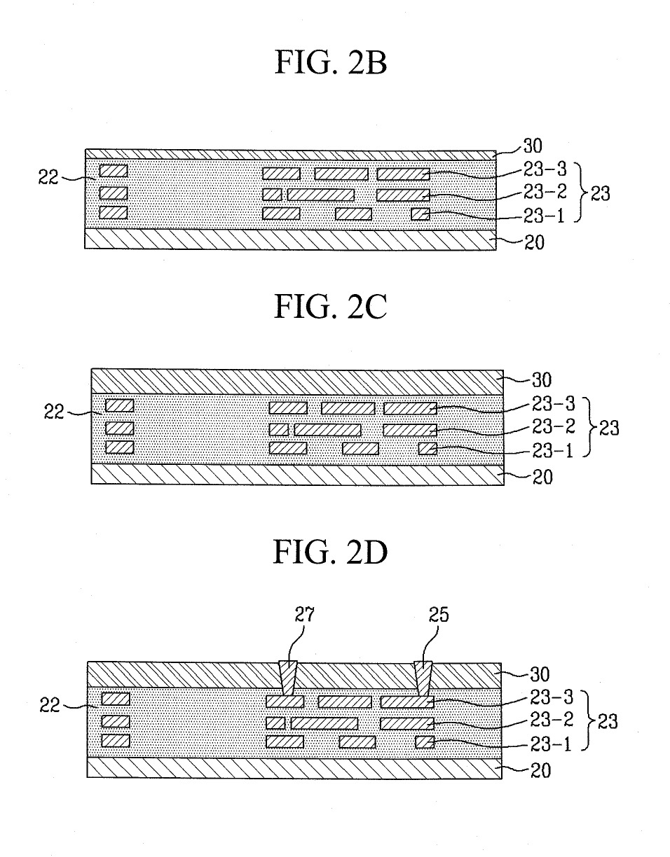

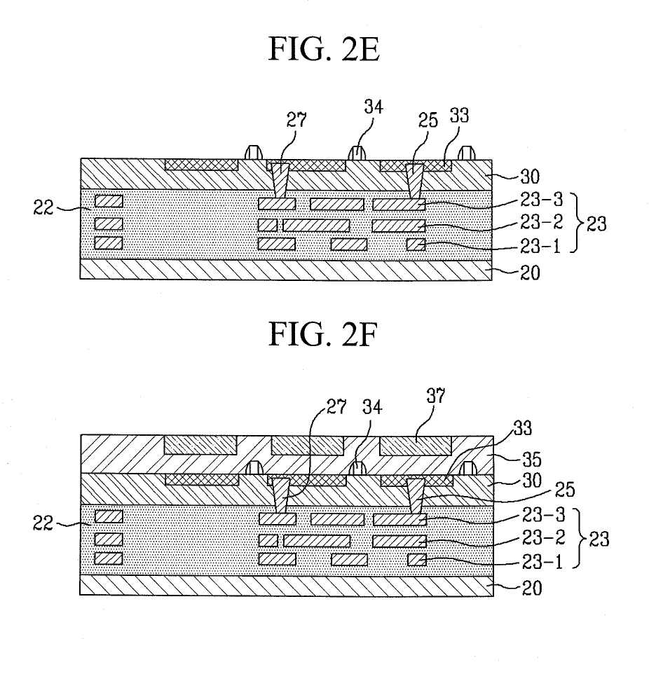

Example FIGS. 2A to 2F illustrate a method for manufacturing a CMOS image sensor in accordance with embodiments.

### DESCRIPTION

Reference will now be made in detail to embodiments, examples of which are illustrated in the accompanying drawings. Wherever possible, the same reference numbers will be used throughout the drawings to refer to the same or like parts.

In accordance with embodiments, differently from a process in which metal wirings are formed after formation of photodiodes and transistors, metal wirings are first formed and, in turn, a silicon layer is deposited on and/or over the metal wirings prior to forming photodiodes and transistors. Further, an electric connection between the previously formed metal wirings and the transistors can be accomplished by using a super via process for connection between pads. Accordingly, omitting a plurality of metal wirings on and/or over the photodiodes is possible, allowing the photodiodes to directly receive light and enhancing light sensitivity. In conclusion, embodiments can solve problems caused by a configuration of stacking metal wirings and a dielectric layer over photodiodes.

As illustrated in example FIG. 2A, dielectric layer 22 containing multilayered metal wirings 23 is formed on and/or over semiconductor substrate 20. The multilayered metal wirings 23 may be composed of one of aluminum (Al) and copper (Cu). For example, after forming a first dielectric layer on and/or over semiconductor substrate 20, a first metal layer may be formed and patterned on and/or over the first dielectric layer to form first metal wiring 23-1. A second dielectric layer may then be formed and flattened on and/or over the first dielectric layer including first metal wiring 23-1. A second metal layer may then be formed and patterned on and/or over the second dielectric layer to form second metal wiring 23-2. A third dielectric layer may then be formed and flattened on and/or over the second dielectric layer including second metal wiring 23-2. A third metal layer may then be formed and patterned on and/or over the third dielectric layer to form third metal wiring 23-3. Dielectric layer 22 may include the first dielectric layer, the second dielectric layer and the third dielectric layer.

In accordance with embodiments, the overall number of metal wirings formed in pixel regions may be smaller than the number of metal wirings formed in logic regions. The reason why the smaller number of metal wirings is formed in the pixel regions is to enhance light receiving capability and integration degree. In the manufacture of semiconductor devices, a variety of configurations are required to form metal wirings. Diffusion of light occurs between a thin transistor activation layer and a thin wiring layer which are formed of different materials. Although the diffusion of light may be used if necessary, it may be undesirable in many instances. In particular, processes accompanying a thermal treatment undergo serious diffusion of light. To prevent this phenomenon, an anti-diffusion layer is preferably formed of a metal material having relatively less diffusion of light, such metal material may be one of Ti, TiN, Ta, TaN and TiSiN. In accordance with embodiments, the anti-diffusion layer is a Ti layer, TiN layer, or the like formed using a deposition process such as a physical vapor deposition (PVD), chemical vapor deposition (CVD), atomic layer deposition (ALD), or the like.

As illustrated in example FIG. 2B, mono-silicon layer 30 is formed on and/or over dielectric layer 22 including metal wirings 23. Mono-silicon layer 30 may be formed by implanting SiH₄ plasma ions into an upper surface of dielectric layer 22. Mono-silicon layer 30 is subsequently processed to a P-type or N-type conductive layer via silicon ion implantation or an epi-process.

As illustrated in example FIG. 2C, mono-silicon layer 30 is subjected to an epitaxial growth process. For example, mono-silicon layer 30 may be grown to a thickness in a range between approximately 3,000 Å to 8,000 Å.

As illustrated in example FIG. 2D, the entire surface of grown mono-silicon layer 30 (hereinafter, silicon layer 30) is coated with a photosensitive layer and then patterned via exposure and developing processes, thereby forming a mask. Silicon layer 30 and dielectric layer 22 are then etched using the mask as an etching barrier to form via-holes exposing the metal wiring (for example, third metal wiring 23-3). Next, a metal material such as tungsten, aluminum, copper, or the like is buried in the via-holes to form a metal layer. The resulting metal layer is planarized using a CMP process to form via-contacts 25 and 27 contacting metal wiring 23-3.

As illustrated in example FIG. 2E, a field oxide layer is then formed on and/or over silicon layer 30 including via-contacts 25 and 27. The field oxide layer may contain a local oxidation of silicon (LOCOS) or shallow trench isolation (STI) configuration. Dopant ions such as N-type dopants may then be implanted into silicon layer 30 to form photodiodes 33 in silicon layer 30 on and/or over via contacts 25 and 27. Photodiodes 33 may contact and overlap via-contacts 25 and 27 formed in the silicon layer 30 to thereby be electrically connected thereto. Subsequently, a plurality of transistors 34 constituting a unit pixel, such as for example, transfer transistors, may then be formed on and/or over silicon layer 30 and spaced from photodiodes 33. Gate electrodes or source/drain regions of transistors 34 may define wirings to be electrically connected to via-contacts 25 and 27.

In the CMOS image sensor in accordance with embodiments, metal wirings 23 formed in dielectric layer 22 and on and/or over silicon substrate 20, are electrically connected to photodiodes 33 and transistors 34 by way of via-contacts 25 and 27 penetrated through silicon layer 30 formed on and/or over dielectric layer 22. Transistors 34 and metal wirings 23 are electrically connected to each other by way of via-contacts 25 and 27. Via-contacts 25 and 27 are formed of a metal such as one of tungsten, aluminum, copper, or the like. Photodiodes 33 may serve as a plurality of dopant diffusion layers formed in silicon layer 30. For example, when silicon layer 30 is a P-type conductive layer, photodiodes 33 may have a P/N/P form including a PO region, n-region, and P+ region sequentially stacked on and/or over the surface of silicon layer 30. The n-region is under a complete depletion condition during operation of photodiodes 33. In a 3-T configuration, transistors 34 include a reset transistor, drive transistor, select transistor, and the like. In a 4-T configuration, a transfer transistor may be further provided. A field oxide layer may be formed on and/or over silicon layer 30 adjacent to photodiodes 33. Via-contacts 25 and 27 to connect transistors 34 constituting a unit pixel to metal wirings 23 therebelow also serve as a light shield to prevent light from entering, for example, transistors 34 except for photodiodes 33.

As illustrated in example FIG. 2F, dielectric layer 35 may then be formed on and/or over silicon layer 30 including transistors 34 and photodiodes 33. A color filter array (CFA) process is subsequently conducted to form color filters 37, serving to realize color images, in dielectric layer 35 at positions spatially corresponding to the respective photodiodes 33. Alternatively, color filters 37 may be formed on and/or over dielectric layer 35.

In the CMOS image sensor in accordance with embodiments, once metal wirings 23 are formed, silicon layer 30 is formed on and/or over metal wirings 23 such that photodiodes 33 and transistors 34, formed on and/or over silicon layer 30, are located on and/or over metal wirings 23. With this arrangement, a logic device having more than six wiring layers can be formed without serious difficulty, thereby enabling the realization of a system-on-chip (SoC) and a core logic technology for 130 nm and 90 nm or less size.

As apparent from the above description, in lieu of a BEOL process employed in the manufacture of a CMOS image sensor in which metal wirings are formed after formation of photodiodes and transistors, in accordance with embodiments, metal wirings are first formed and in turn, a silicon layer is deposited on and/or over the metal wirings prior to forming photodiodes and transistors. Such a manufacturing process has the following effects. Firstly, a minimization in light loss is possible, maximizing performance of a CMOS Image Sensor (CIS). Secondly, a lens forming process can be eliminated, reducing overall manufacturing time. Thirdly, photodiodes can be formed regardless of the presence of a metal layer, and this can maximize the degree of integration of pixels.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A CMOS image sensor comprising:
a semiconductor substrate;
a first dielectric layer formed over the semiconductor substrate;
a metal wiring formed over the first dielectric layer;
a silicon layer formed over the first dielectric layer including the metal wiring;
a photodiode formed in the silicon layer;
a plurality of transistors formed over the silicon layer;
via-contacts extending through the silicon layer to connect the photodiode and the metal wiring to each other;
a second dielectric layer formed over the silicon layer including the transistors and the photodiodes; and
a color filter formed at the second dielectric layer corresponding spatially to the photodiode.

2. The CMOS image sensor of claim 1, wherein the metal wiring has a multilayer form.

3. The CMOS image sensor of claim 1, wherein the metal wiring is composed of any one of tungsten, aluminum, and copper.

4. The CMOS image sensor of claim 1, further comprising an anti-diffusion layer formed over the metal wiring.

5. The CMOS image sensor of claim 4, wherein the anti-diffusion layer comprises a metal material.

6. The CMOS image sensor of claim 5, wherein the metal material is any one of Ti, TiN, Ta, TaN and TiSiN.

7. The CMOS image sensor of claim 1, wherein the color filter is formed on the second dielectric layer.

8. The CMOS image sensor according to claim 1, wherein the color filter is formed in the second dielectric layer.

9. The CMOS image sensor according to claim 1, wherein the color filter is formed over the second dielectric layer.

10. A method for manufacturing a CMOS image sensor comprising:
forming a first dielectric layer over a semiconductor substrate; and then
forming a metal wiring over the first dielectric layer; and then
forming a silicon layer over the first dielectric layer including the metal wiring; and then
forming via-contacts extending through the silicon layer and connected to the metal wiring; and then
forming a photodiode in the silicon layer; and then
forming a plurality of transistors over the silicon layer adjacent to the photodiode; and then
forming a second dielectric layer over the silicon layer including the transistors and the photodiodes; and then
forming a color filter over the second dielectric layer and corresponding to the photodiode.

11. The method of claim 10, wherein forming the photodiode comprises implanting a dopant into the silicon layer.

12. The method of claim 9, wherein forming the photodiode comprises forming the photodiode over and contacting the via-contacts.

13. The method of claim 10, wherein forming the via-contacts comprises:
forming a photosensitive layer over the entire surface of the silicon layer and patterning the photosensitive layer via exposure and developing processes, so as to form a mask; and then
etching the silicon layer and first dielectric layer using the mask as an etching barrier to form via-holes exposing the metal wiring; and then
forming a metal layer buried in the via-holes and planarizing the metal layer to form the via-contacts.

14. The method of claim 13, wherein the metal layer is composed of one of tungsten, aluminum and copper.

15. The method of claim 10, wherein forming the silicon layer comprises:
forming a mono-silicon layer over the first dielectric layer; and
growing the mono-silicon layer using an epitaxial process.

16. The method of claim 15, wherein forming the mono-silicon layer comprises performing an implantation to implant SiH₄ plasma ions in the upper surface of the first dielectric layer.

17. The method of claim 16, wherein the mono-silicon layer is grown to a thickness in a range between approximately 3,000 Å to 8,000 Å.

18. The method of claim 17, wherein the mono-silicon layer is doped to P-type or N-type.

19. A method comprising:
forming a lower dielectric layer over a semiconductor substrate; and then
forming a metal wiring over the lower dielectric layer; and then
forming a silicon layer over the lower dielectric layer including the metal wiring; and then
form a via-hole extending the silicon layer and the lower dielectric layer thereby exposing a portion of the metal wiring; and then
forming a via contact in the via hole and contacting the metal wiring; and then
forming a photodiode in the silicon layer and covering at least an upper portion of the via contacts by implanting dopant ions into the upper surface of the silicon layer; and then
forming a transistor over the silicon layer and spaced laterally from the photodiodes; and then
forming an upper dielectric over the silicon layer including the transistor and the photodiode; and then
forming a color filter at the upper dielectric layer spatially corresponding to the photodiode,
wherein the photodiode and the transistor are formed after forming the metal line.

20. The method of claim 19, wherein the color filter is formed in the dielectric layer.
